(19) United States
(12) Patent Application Publication
(10) Pub. No.: US 2021/0248917 A1
(43) Pub. Date: Aug. 12, 2021

(54) METHOD AND SYSTEM OF MEASURING SPATIAL ABILITY REQUIRED FOR ARCHITECTURE OR INTERIOR DESIGN

(71) Applicant: UNIVERSITY-INDUSTRY COOPERATION GROUP OF KYUNG HEE UNIVERSITY, Yongin-si (KR)

(72) Inventors: Ji Young Cho, Seoul (KR); Joori Suh, Cincinnati, OH (US)

(21) Appl. No.: 16/985,338

(22) Filed: Aug. 5, 2020

(30) Foreign Application Priority Data
Feb. 7, 2020 (KR) 10-2020-0015073
Apr. 16, 2020 (KR) 10-2020-0046174

(51) Int. Cl. G09B 7/06; G09B 19/00; G06T 19/20

(52) U.S. Cl. CPC G09B 7/06; G06T 2219/2016; G06T 19/20; G09B 19/00

(57) ABSTRACT

A method and system of measuring a domain specific spatial ability required in the field of architecture or interior design are disclosed.

In the method, in order to measure a spatial ability of a user, one or more of a mental rotation measurement and a spatial visualization measurement for the user is first performed. Then, the spatial ability for the user is evaluated according to a result of performing one or more measurements. Then, the evaluated result is provided to the user as a domain specific spatial ability required in the field of architecture or interior design. Here, the mental rotation measurement is performed by measuring a rotation state estimation ability for a 3D figure, and the spatial visualization measurement is performed by measuring ability of translating 3D spatial information into 2D spatial information and an ability of translating a 2D spatial information into a 3D spatial information.

### CROSS-REFERENCE TO RELATED APPLICATION

This application claims priority to and the benefit of Korean Patent Application No. 10-2020-0015073 filed in the Korean Intellectual Property Office on Feb. 7, 2020, Korean Patent Application, and Korean Patent Application No. 10-2020-0046174 filed in the Korean Intellectual Property Office on Apr. 16, 2020, the entire contents of which are incorporated herein by reference.

### BACKGROUND OF THE INVENTION

### (a) Field of the Invention

The present invention relates to a method and system of measuring a spatial ability required for architecture or interior design.

### (b) Description of the Related Art

Architecture and interior design include a process of creating and testing a spatial idea, which is expressed in two-dimensional (2D) or three-dimensional (3D) shapes and forms. Architects and interior designers eventually create a three-dimensional space through spatial design, and in the design process, spatial ideas are expressed through 2D drawings such as floor plans, elevations, and cross-sectional views, and 3D media such as models, perspective views, sketches, and the like, and spatial ability that allows a viewer to smoothly infer and convert these 2D and 3D information into each other is considered to be an essential ability in performing architecture and interior design. The spatial ability largely consists of two types: mental rotation and spatial visualization.

Among the existing methods of measuring spatial ability, mental rotation measurement is performed by using, for example, as shown in FIGS. 1(a)-1(e), an integral form of small connected cubes. For example, the mental rotation measurement (mental rotation test developed by Peters et al. (1995) as a specific example) is performed by asking a viewer to imagine a form of rotating a figure shown in FIG. 1(a) with respect to a vertical axis, and find two matching figures among figures shown in FIG. 1(b), FIG. 1(c), FIG. 1(d), and FIG. 1(e) corresponding to an imagined rotated form of the figure shown in FIG. 1(a).

In addition, among existing measurement methods of spatial ability, spatial visualization measurement (paper folding test developed by Ekstrom, French, Harman, and Dermen (1976) as a specific example) is performed by using a method of folding paper as shown in FIGS. 2(a)-2(g). Spatial visualization is measured by asking a viewer to imagine folding the paper shown in FIG. 2(a) in half and forming a hole in the paper folded in half as shown in FIG. 2(b), and then finding a correct shape among the figures shown in FIG. 2(c), FIG. 2(d), FIG. 2(e), FIG. 2(f), and FIG. 2(g) that shows the positions of the holes when the paper is completely unfolded.

In the existing mental rotation measuring method (FIGS. 1(a)-1(e)), an integral form of small connected cubes is used, which includes only one connected form, however ‘space’ or ‘spatial relationship’ between forms that are important elements in architecture or interior design have not been considered. Therefore, a method of performing mental rotation measurement using questions consisting of forms including characteristics of ‘space’ and ‘spatial relationship’ is required.

In addition, in the existing spatial visualization method, since only the form of folding the paper and forming the hole is used, similarly, the characteristics of ‘space’ or ‘spatial relationship’ which are important elements in architecture or interior design, as well as the elements of visualization that fit an eye level of a person have been excluded. Therefore, a method of performing spatial visualization measurement using questions composed of forms that include the characteristics of ‘space’ and ‘spatial relationship’ and the elements of visualization that fit the eye level of a person is required.

### SUMMARY OF THE INVENTION

The present invention has been made in an effort to provide a method and system of measuring spatial ability required for architecture or interior design that may provide high reliability in measuring spatial ability in the architecture or interior design.

An embodiment of the present invention provides a method of measuring a domain specific spatial ability required in the field of architecture or interior design, including: in order to measure a spatial ability for a user, (1) performing one or more of a mental rotation measurement and a spatial visualization measurement for the user; (2) evaluating a spatial ability for the user according to a result of performing the one or more measurements; and (3) providing the evaluated result to the user as a spatial ability required for the user's architecture or interior design, wherein the mental rotation measurement is performed by measuring a rotation state estimation ability for a 3D figure, and the spatial visualization measurement is performed by measuring an ability of estimating (or translating) a 3D figure based on a 2D figure and an ability of estimating a 2D figure based on a 3D figure.

The mental rotation measurement includes a first mental rotation (MR_1) that measures a state estimation ability after rotation of a 3D figure at a predetermined angle based on a vertical axis, and a second mental rotation (MR_2) that measures rapidity of rotation of a 3D figure at least one or more times in up, down, left, and right directions.

The first mental rotation measurement, MR_1, is performed by a method in which, after providing a 3D figure as a question to the user and providing a plurality of 3D figures of different shapes as examples, the user estimates a state after mentally rotating the 3D figure of the question based on the vertical axis and then selects as an answer a matching 3D figure from the example figures.

The second mental rotation measurement, MR_2, is performed by a method in which, after providing a 3D figure as a question to the user and providing another 3D figure as an example formed by the 3D figure of the question being rotated at least one or more times in up, down, left, and right directions, a time until the user rotates the 3D figure of the question at least one or more times in up, down, left, and right directions to match the 3D figure of the example is measured. After the 3D figure of the question and the 3D figure of the example are displayed to the user through a virtual reality display, the second mental rotation, MR_2 is performed by rotating the 3D figure of the question through the virtual reality display.

The spatial visualization measurement includes followings: (1) a first spatial visualization measurement, SV_A, that measures a visualization ability of a 3D space through a partial 2D planar cross-sectional view of a 3D figure viewed from a predetermined direction, (2) a second spatial visualization measurement, SV_I, that measures a visualization ability of a 3D external perspective or a 3D internal perspective through at least one 2D planar cross-sectional view of a 3D model having at least one or more floors, and (3) a third spatial visualization measurement, SV_II, that measures an visualization ability of a corresponding 2D planar cross-sectional view through a 3D exterior perspective or a 3D interior perspective.

The first spatial visualization measurement, SV_A, is performed by a method in which, after providing a partial 2D planar cross-sectional view—in the partial 2D cross-sectional view, one side thereof is open, and an arrow of a type viewed from the opened side is indicated—of a 3D figure to the user as a question and providing a plurality of 3D figures having different shapes as an example, the user estimates a 3D internal space image when looking at the partial 2D planar cross-sectional view in the direction of the arrow and then selects a matching 3D figure with the estimated internal space from the figures of the example as an answer.

The second spatial visualization measurement, SV_I, is performed by a method in which, after providing at least one 2D planar cross-sectional view of a 3D model having at least one or more floors to the user as a question and providing a plurality of 3D models having different shapes as an example, the user estimates a 3D perspective or a 3D internal perspective of the 2D planar cross-sectional view provided in the question and then selects a matching 3D model as an answer.

The third spatial visualization measurement, SV_II, is performed by a method in which, after providing a perspective of a 3D model or a 3D interior space as a question and providing a plurality of 2D planar cross-sectional views having different shapes as an example, the user estimates a 2D planar cross-sectional view of the 3D model or a 3D interior space and then selects a matching 2D planar cross-sectional view as an answer.

The performing of one or more of the mental rotation measurement and the spatial visualization measurement for the user includes: acquiring a 2D or 3D figure corresponding to a pre-stored question for the mental rotation measurement or the spatial visualization measurement and a 2D or 3D figure corresponding to the example; presenting a question including the 2D or 3D figure corresponding to the question and the options of 2D or 3D figures corresponding to the question to the user; receiving an answer to the question from the user to determine if the received answer is correct; and setting a correct answer to a preset question for the mental rotation measurement or the spatial visualization measurement as a result of performing the measurement.

The presenting of the question to the user includes the following three methods: (1) displaying the question to the user using printed paper copy; (2) displaying the question to the user using computer screens or other electronic visual display from program; and (3) displaying the question to the user through a virtual reality display or an augmented display; the receiving of the answer to the question from the user to determine whether the received answer is correct includes measuring a time until the user rotates a 3D figure corresponding to the question displayed on the virtual reality display in at least one of up, down, left, and right directions to match the 3D figure corresponding to the example; and the setting as the result of performing the measurement includes setting the time measured for the question as the result of performing the measurement.

The performing of one or more of the mental rotation measurement and the spatial visualization measurement for the user includes: acquiring a basic 3D figure corresponding to a pre-stored question for the mental rotation measurement or the spatial visualization measurement; generating a 2D or 3D figure corresponding to a question and a 2D or 3D figure corresponding to an example in real time by using the basic 3D figure; presenting a question including the 2D or 3D figure corresponding to the question generated in real time and the 2D or 3D figure corresponding to the example to the user; receiving an answer to the question from the user and determining whether the received answer is correct; and setting a correct answer to a preset question for the mental rotation measurement or the spatial visualization measurement as a result of performing the measurement.

Another embodiment of the present invention provides a system of measuring a spatial ability required for architecture or interior design, including an input/output part, a memory, and a processor, wherein the input/output part displays information or outputs voice to the outside and receives information or instructions inputted from the outside; the memory is configured to store a set of codes; the codes control the processor to execute a process of performing one or more of mental rotation measurement and spatial visualization measurement for the user based on display of information through the input/output part and input from a user, a process of evaluating a spatial ability for the user according to a result of performing the one or more measurements, and a process of providing the evaluated result of spatial ability required for the user's architecture or interior design to the user through the input/output part; and the mental rotation measurement is performed by measuring a rotation state estimation ability for a 3D figure, and the spatial visualization measurement is performed by measuring an ability of estimating a 3D figure based on a 2D figure and an ability of estimating a 2D figure based on a 3D figure.

The processor, for the mental rotation measurement, measures an ability of accurately estimating a state after rotation at a predetermined angle based on a vertical axis of a 3D figure, and further executes a process of measuring rapidity of rotation of at least one or more times in up, down, left, and right directions of a 3D figure.

The spatial ability measurement system further includes a virtual reality display and augmented reality display, and the processor uses the virtual reality and augmented display to execute the process of measuring the rapidity and accuracy of rotation of at least one or more times in up, down, left, and right directions of the 3D figure.

The processor, for the spatial visualization measurement, further executes a process of measuring a visualization ability of a 3D interior space when a partial 2D planar cross-sectional view of a 3D model is viewed from a predetermined direction, a process of measuring the visualization ability of a 3D perspective or a 3D internal perspective through at least one 2D planar cross-sectional view of the 3D model having at least one or more floors, and a process of measuring a visualization ability of a 2D planar cross-sectional view through a 3D exterior perspective or a 3D interior perspective.

The processor, when executing the process of performing the one or more of the mental rotation measurement and the spatial visualization measurement for the user, further executes a process of acquiring a 2D or 3D figure corresponding to a pre-stored question and a 2D or 3D figure corresponding to a pre-stored example and providing them to the user through the input/output part, and a process of receiving an answer inputted from the user through the input/output part and setting it as the result of performing the measurement.

The processor, when executing the process of performing the one or more of the mental rotation measurement and the spatial visualization measurement for the user, further executes a process of acquiring a basic 3D figure corresponding to a pre-stored question, a process of generating a 2D or 3D figure corresponding to the question and a 2D or 3D figure corresponding to the example in real time by using the acquired basic 3D figure and then providing them to the user through the input/output part, and a process of receiving an answer inputted from the user through the input/output part and setting it as the result of performing the measurement.

While the conventional method of measuring spatial ability, such as mental rotation test (as shown in FIG. 1) and paper folding test (as shown in FIG. 2), uses only small object-oriented figures and paper shapes, the present invention has an environmental scale mainly used in architecture or interior design. Moreover, according to correlation measurement between these conventional measurement and design progress ability performed several times, no correlation was reported, indicating these conventional measurement cannot estimate the ability essential in architecture or interior design performance.

In addition, according to correlation measurement between design progress ability performed several times and spatial ability measurement for architecture/interior design, the spatial ability for architecture/interior design has a positive correlation with ability of performing the architecture/interior design. These indicate that prior existing measurement general spatial ability while the present invention measures architecture and interior design domain specific spatial ability. According to the present invention, since it is possible to predict a part of 3D spatial design performance related to creativity, it is possible to provide high reliability in measuring spatial ability of architecture/interior design.

According to the present invention, it is possible to improve the spatial ability through regular performance.

In addition, after measuring the spatial ability according to the present invention, when a low spatial ability result is obtained in a specific item, user-customized training may be provided by providing training on a corresponding part.

Further, it can be used as a measurement tool for evaluating vocational skills that require spatial ability of environmental scales such as quickly recognizing and visualizing two-dimensional and three-dimensional spaces.

### BRIEF DESCRIPTION OF THE DRAWINGS

FIGS. 1(a)-1(e) illustrate a schematic view of an example of an existing general method of measuring mental rotation ability among spatial ability according to the prior art (developed by Peters et al. (1995)).

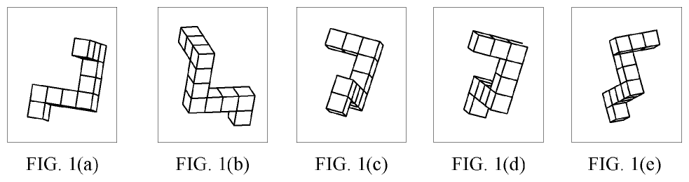

FIGS. 2(a)-2(g) illustrate a schematic view of an example of an existing general method of measuring spatial visualization ability among spatial ability according to the prior art (developed by Ekstrom, French, Harman, and Dermen (1976)).

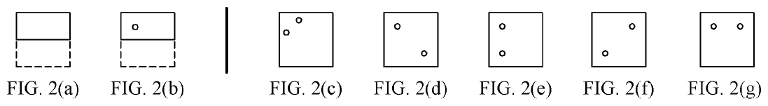

FIG. 3 illustrates a schematic block diagram of a spatial ability measurement system according to an embodiment of the present invention.

FIG. 4 illustrates a schematic flowchart of a method of measuring a spatial ability according to an embodiment of the present invention.

FIGS. 5(a)-5(e) illustrate a schematic view of a measurement item of mental rotation 1 (MR_1) of a mental rotation method among spatial ability measurement methods according to an embodiment of the present invention.

FIGS. 6(a)-6(b) illustrate a schematic view of a measurement item of mental rotation 2, (MR_2), of a mental rotation method among spatial ability measurement methods according to an embodiment of the present invention.

FIGS. 7(a)-7(e) illustrate a schematic view of a measurement item of spatial visualization 1A, (SV_IA) of a spatial visualization method among spatial ability measurement methods according to an embodiment of the present invention.

FIGS. 8(a)-8(e) illustrate a schematic view of a measurement item of spatial visualization (SV_I), of a spatial visualization method based on exterior perspectives among spatial ability measurement methods according to an embodiment of the present invention.

FIGS. 9(a)-9(e) illustrate a schematic view of another example of a measurement item of spatial visualization 1, (SV_IA), of a spatial visualization method based on interior perspectives among spatial ability measurement methods according to an embodiment of the present invention.

FIGS. 10(a)-10(e) illustrate a schematic view of a measurement item of spatial visualization II, (SV_II), of a spatial visualization method based on interior perspectives among spatial ability measurement methods according to an embodiment of the present invention.

FIGS. 11(a)-11(e) illustrate a schematic view of another example of a measurement item of spatial visualization II, (SV_II), of a spatial visualization method based on exterior perspectives among spatial ability measurement methods according to an embodiment of the present invention.

FIG. 12 illustrates a detailed flowchart of steps for performing spatial ability measurement illustrated in FIG. 4.

FIG. 13 illustrates another flowchart of steps for performing spatial ability measurement illustrated in FIG. 4.

FIG. 14 illustrates another flowchart of steps for performing spatial ability measurement illustrated in FIG. 4.

### DETAILED DESCRIPTION OF THE EMBODIMENTS

Hereinafter, the present invention will be described more fully with reference to the accompanying drawings, in which exemplary embodiments of the invention are shown. As those skilled in the art would realize, the described embodiments may be modified in various different ways, all without departing from the spirit or scope of the present invention. Accordingly, the drawings and description are to be regarded as illustrative in nature and not restrictive. Like reference numerals designate like elements throughout the specification.

In the present specification, unless explicitly described to the contrary, the word “comprise” and variations such as “comprises” or “comprising” will be understood to imply the inclusion of stated elements but not the exclusion of any other elements. In addition, the terms “-er”, “-or”, and “module” described in the specification mean units for processing at least one function and operation, and can be implemented by hardware components or software components and combinations thereof.

An apparatus, a device, and a server described in the present invention are composed of hardware including at least one processor, memory, communication apparatus, etc., and a program executed in combination with hardware is stored in a designated location or on the internet website. The hardware has a configuration and performance to implement a method of the present invention. The program includes instructions that implement the method of operation of the present invention described with reference to the drawings, and executes the present invention in combination with hardware such as a processor and a memory.

Hereinafter, a spatial ability measurement system according to an embodiment of the present invention will be described.

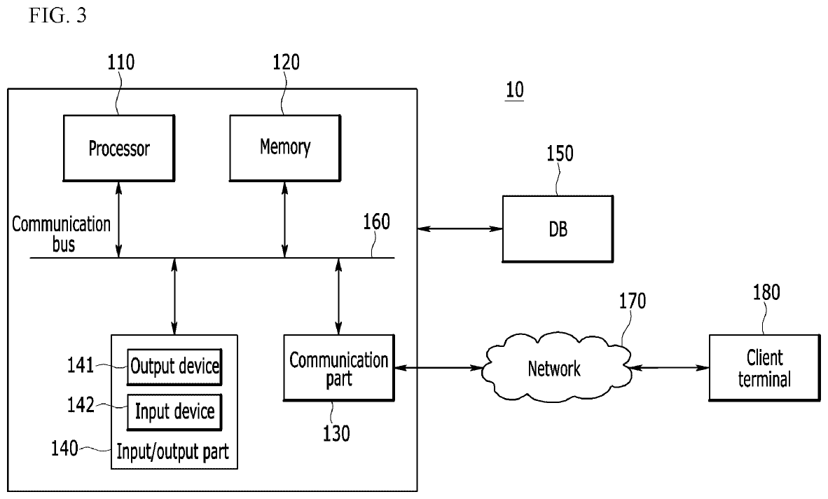

FIG. 3 illustrates a schematic block diagram of a spatial ability measurement system according to an embodiment of the present invention.

As shown in FIG. 3, a spatial ability measurement system 10 according to the embodiment of the present invention includes at least one processor 110, a memory 120, a communication part 130, an input/output part 140, and a database (DB) 150.

The processor 110 may be a general-purpose central processing unit (CPU), a microprocessor, an application-specific integrated circuit (ASIC), or one or more integrated circuits for controlling program execution in the solution of the present application. The processor 110 may be connected to the memory 120, the communication part 130, the input/output part 140, and the DB 150 through a communication bus 160.

The memory 120 may be a read-only memory (ROM), a static storage device that can store instructions, a random access memory (RAM), a dynamic storage device that can store information and instructions, an electrically erasable programmable read-only memory (EEPROM), a compact disc read-only memory (CD-ROM), another compact disc storage device, other optical disc storage devices (including a compressed optical disc, a laser disc, an optical disc, a digital versatile disc, a Blu-ray disc, etc.), a magnetic disk storage media, other magnetic storage devices, or a medium that can be accessed by a computer while carrying or storing expected program code in a form of an instruction or data structure, but it is not limited. The memory 120 may independently exist.

Alternatively, the memory 120 may be additionally configured to store program code. By accessing the program code stored in the memory 120, the processor 110 executes processing for performing a method of measuring a spatial ability according to the embodiment of the present invention, which will be specifically described below.

The communication part 130 may communicate with other devices or communication networks, which may be implemented by various communication technologies. That is, a Wi-Fi, wideband CDMA (WCDMA), high speed downlink packet access (HSDPA), high speed uplink packet access (HSUPA), high speed packet access (HSPA), mobile WiMAX, WiBro, long term evolution (LTE), Bluetooth, infrared data association (IrDA), near field communication (NFC), Zigbee, wireless LAN technology, or the like, may be applied thereto. For example, the communication part 130 allows the processor 110 to communicate with the DB 150 to transmit and receive various data. In addition, when connected to a network 170 such as the Internet to provide a spatial ability measurement service through a client terminal 180, it is possible to follow TCP/IP which is a standard protocol for information transmission in the network 170.

The input/output part 140 specifically includes an output device 141 and an input device 142, and the output device 141 may communicate with the processor 110 and may display information or output voice in a plurality of ways. For example, the output device 141 may be a liquid crystal display (LCD), a light emitting diode (LED) display, an organic light emitting diode (OLED) display, a speaker, or the like. The input device 142 may communicate with the processor 110 and receive user input in a plurality of ways. For example, the input device 142 may be a mouse, keyboard, touch screen, or sensing device.

The DB 150 stores and manages various data used to provide a service according to the spatial ability measurement method according to the embodiment of the present invention. The DB 150 may include at least one storage medium of a flash memory, a hard disk, a multimedia card micro type of memory, a card type of memory (for example, SD or XD memory), a random access memory (RAM), a static random access memory (SRAM), a read only memory (ROM), an electrically erasable programmable read only memory (EEPROM), a programmable read only memory (PROM), a magnetic memory, a magnetic disk, and an optical disk, but it is not limited thereto, and may include any medium capable of storing data. In addition, although FIG. 3 illustrates that the DB 150 is separated from the memory 120, this is only one example, and unlike this, the DB 150 may be integrated with the memory 120. Further, in addition to transmitting and receiving data through the communication part 130, the DB 150 may be directly or indirectly connected to the communication bus 150 and directly connected to the processor 110.

Specifically, the DB 150 includes a content used for the spatial ability measurement according to the embodiment of the present invention. For example, a content corresponding to various questions used to measure a mental rotation ability and a spatial visualization ability that are spatial abilities, a content of evaluation criteria used to evaluate the spatial abilities based on results of solving the questions, and the like are included. Here, the content corresponding to the question includes a 2D or 3D figure shape corresponding to the question, a 2D or 3D figure shape corresponding to the example, and a correct answer. In addition, the above-described figure shape may include a virtual reality-based figure shape. The figure shape will be described later in detail.

The communication bus 160 may be a peripheral component interconnect (PCI) bus, an extended industry standard architecture (EISA) bus, or the like.

As described above, a method for measuring a spatial ability required for architecture or interior design by using the system 10 according to the embodiment of the present invention having the configuration described above will be described with reference to the drawings.

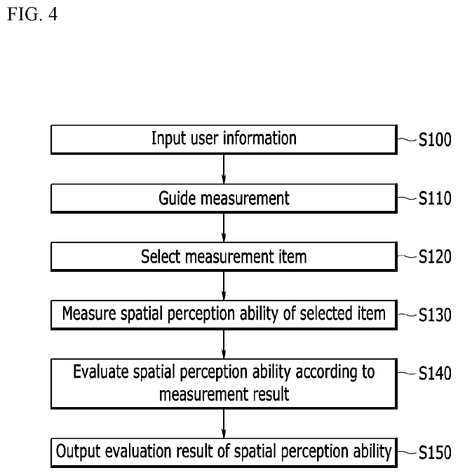

FIG. 4 illustrates a schematic flowchart of a method of measuring a spatial ability according to an embodiment of the present invention. The method of measuring the spatial ability according to the embodiment of the present invention may be performed by the spatial ability measurement system 10 described above, specifically, the processor 110.

Referring to FIG. 4, first, information of a user performing spatial ability measurement according to the embodiment of the present invention is received and stored (S100). Here, the user's information may be stored in the memory 120 or DB 150 described above. Hereinafter, ‘store’ or ‘stored’ means that target data being stored is stored in the memory 120 or DB 150 even if there is no specific description.

Next, a guide for the method of performing the spatial ability measurement according to the embodiment of the present invention is performed (S110). The guide may include descriptions for items for performing the spatial ability measurement according to the embodiment of the present invention, that is, a description of measurement items according to the mental rotation measurement method and the spatial visualization measurement method that are two measurement methods, and a description of a method of performing each measurement item. As will be described later, in the embodiment of the present invention, two measurement items are used in the mental rotation measurement method, and three measurement items are used in the spatial visualization measurement method. In the embodiment of the present invention, only the above-mentioned five measurement items will be described, but the present invention is not limited thereto. That is, items required for each spatial ability measurement method may be added, or some items therefor may be removed. Therefore, according to the guide, a user selects an item to be measured. Generally, it is possible to select all the measurement items corresponding to the spatial ability measurement in a sequentially performed form, but when there are measurement items already performed among the measurement items, only the remaining measurement items may be selected.

Accordingly, when a measurement item for performing the spatial ability measurement is selected according to the guide in step S110 (S120), spatial ability measurement corresponding to the selected measurement item is performed (S130). A method of specifically measuring the spatial ability for each item will be described in detail later.

Thereafter, the spatial ability for the user is evaluated according to the result of measuring the spatial ability of the selected item (S140). In this case, the evaluation of the spatial ability for the user may be performed by using a preset evaluation criterion stored in the DB 150 for the result of measuring the spatial ability of the selected item. This evaluation criterion may be statistically or experimentally set in advance by reflecting the measurement results performed for each item of the spatial ability measurement method over many times for many users.

Finally, the evaluation result of the spatial ability for the user performed in step S140 is outputted to the researchers or/and user (S150). The output may be performed in a form of a display through a screen or the like by the output device 141.

Hereinafter, a spatial ability measurement method according to an embodiment of the present invention will be described in detail.

First, a summary of each item of the spatial ability measurement method according to the embodiment of the present invention is shown in [Table 1].

TABLE 1

| | | | | Number |
|---|---|---|---|---|
| | Method-specific | Measurement | Composition | of |
| | item | content | principle | questions |
| Mental rotation | Mental rotation 1 | Measurement of | 3D forms having | 14 |
| method | (MR_1) | ability to quickly | various | |
| | | and accurately | thicknesses, | |
| | | rotate three- | lengths, heights, | |
| | | dimensional form | volumes, etc. | |
| | | by using brain | and with space | |
| | | | therebetween | |
| | Mental rotation 2 | Measurement of | 3D forms having | 14 |
| | (MR_2) | ability to quickly | various | |
| | | and accurately | thicknesses, | |
| | | rotate 3D form- | lengths, heights, | |
| | | measure time | volumes, etc. | |
| | | taking to solve | and with space | |
| | | question | therebetween | |
| | | | Measure time to | |
| | | | rotate figure to | |
| | | | match figure | |
| Spatial | Spatial | Measurement of | 2D plan view of | 14 |
| visualization | visualization IA | ability to read, | various abstract | |
| method | (2D->3D IA, SV IA) | expand, and | 3D forms having | |
| | | convert abstract | various | |
| | | 2D information | thicknesses, | |
| | | into 3D volume | lengths, heights, | |
| | | by considering | volumes, etc. | |
| | | viewing point | Consists of | |
| | | | elements of | |
| | | | visualization that | |
| | | | match space, | |
| | | | relationship, and | |
| | | | eye level. | |
| | Spatial | Measurement of | 2D plan views of | 20 |
| | visualization I | ability to expand | various 3D spatial | |
| | (2D->3D, SV I) | 2D information | models having | |
| | | (planar structure) | various | |
| | | to 3D volume | thicknesses, | |
| | | | lengths, depth, | |
| | | | heights, volumes, | |
| | | | openings, etc. | |
| | | | All consists | |
| | | | of specific | |
| | | | architecture/ | |
| | | | interior | |
| | | | design drawing | |
| | | | elements | |
| | Spatial | Measurement of | 3D spatial models | 10 |
| | visualization II | ability to convert | having various | |
| | (3D->2D, SV II) | 3D information to | thicknesses, | |
| | | 2D information | lengths, depth, | |
| | | (planar structure) | heights, volumes, | |
| | | | openings, etc. | |
| | | | and their 2D | |
| | | | plan views. | |
| | | | All consists | |
| | | | of specific | |
| | | | architecture/ | |
| | | | interior | |
| | | | design drawing | |
| | | | elements | |

As shown in [Table 1], among the spatial ability measurement method according to the embodiment of the present invention, there are two items of mental rotation 1 (MR_1) and mental rotation 2 (MR_2) in the mental rotation method, and there are three items of spatial visualization (2D->3D IA, SV_IA), spatial visualization I (2D->3D, SV I), and spatial visualization II (3D-2D, SV II) in the spatial visualization method.

First, MR_1 of the mental rotation method will be described. As shown in [Table 1], the measurement item of MR_1 is an item for measuring ability to quickly and accurately rotate a three-dimensional form by using a brain. The item consists of 3D forms having various thicknesses, lengths, heights, volumes, etc. and with a space therebetween.

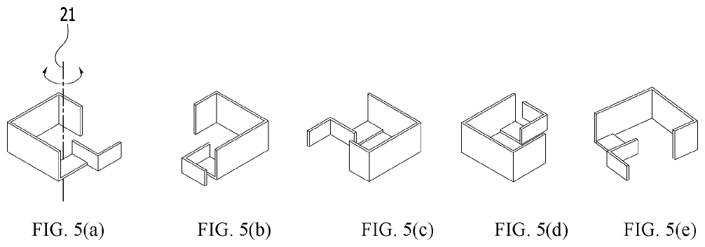

FIGS. 5(a)-5(e) illustrate a schematic view of a measurement item of MR_1 of a mental rotation method among spatial ability measurement methods according to an embodiment of the present invention.

FIG. 5(a) is a figure corresponding to a question for measuring MR_1, and among figures shown as examples in FIG. 5(b), FIG. 5(c), FIG. 5(d), and FIG. 5(e), two corresponding correct answer figures are selected by imagining the figure shown in FIG. 5(a) rotated based on a vertical axis 21. Among the figures as the examples, there may be one or more correct answers, and in the example of FIG. 5(c) and FIG. 5(e) are correct answers, which correspond to the form that may appear when the figure shown in FIG. 5(a) is rotated based on the vertical axis 21.

User's answer input for the measurement item of MR_1 illustrated in FIGS. 5(a)-5(e) may be measured and used together with whether the answer is correct or incorrect and a time at which the answer is inputted. In this case, the spatial ability measurement system 10 shown in FIG. 3 may further include a timer (not shown) used to measure the time, or the processor 110 may measure the time in software by an application stored in the memory 120.

For the measurement item of MR_1, as described above, it is performed by imagining a rotation form of a 3D figure and then submitting an answer (two matching figures), and in this case, for example, a total of 14 questions (but not limited thereto) may be presented to measure the item of MR_1 for the user.

The spatial ability measurement system 10 in FIG. 3 stores the figures of the questions, the figures of the examples, and the correct answers for the questions corresponding to the measurement item of MR_1 in the DB 150, and when the measurement item of MR_1 is selected by the user, a corresponding question may be extracted from the DB 150 and displayed to the user through the output device 141, and an answer may be inputted from the user through the input device 142. Alternatively, the questions corresponding to the measurement item of MR_1 may be presented to the user in a form printed on paper, and an answer to each question may be received through the input device 142.

Meanwhile, in the above, it has been described that the figures of the questions, the figures of the examples, and the correct answers are stored in the DB 150 with respect to the questions of the measurement item of MR_1 but the present invention is not limited thereto, and may be variously implemented. For example, only the figure corresponding to the question of the measurement item of MR_1 is stored in the DB 150, and when the question is displayed to the user, the corresponding figure may be presented as a question, and the figure after the corresponding figure is rotated at an arbitrary rotation angle based on the vertical axis may be provided as an example of the correct answer. In this case, another figure, for example, a figure in which a figure of the correct answer after being rotated at an arbitrary rotation angle is inverted based on a vertical plane may be provided as a figure of a wrong answer, but the present invention is not limited thereto, and figures corresponding to other types of incorrect answers may be provided. As such, in a state in which only the figure of the question corresponding to the measurement item of MR_1 is stored in the DB 150, it is possible to generate and present figures corresponding to an example in real time when the question is presented to the user.

Next, mental rotation 2 (MR_2) of the mental rotation method will be described. As shown in [Table 1], the measurement item of MR_2 is an item for measuring the ability to quickly and accurately rotate the 3D forms, and measures a time required to solve the question. This measurement item consists of 3D forms having various thicknesses, lengths, heights, volumes, etc. and with a space therebetween, and particularly, it may be performed on an electronic display or in a virtual reality basis by using a virtual reality (VR) display (not shown) or an augmented reality (AR) display.

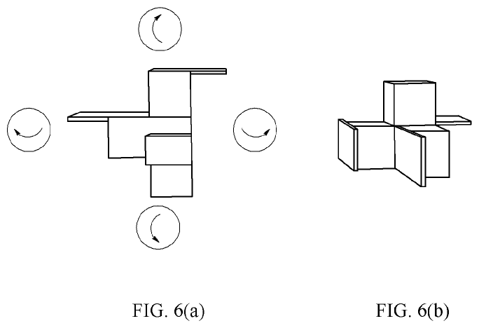

FIGS. 6(a)-6(b) illustrate a schematic view of a measurement item of MR_2 of a mental rotation method among spatial ability measurement methods according to an embodiment of the present invention.

FIG. 6(a) is a basic figure that corresponds to a question for measuring MR_2. The user is asked to match a figure in FIG. 6(b) by indicating rotation directions of up, down, left, and right based on a center of the basic figure and the system measures a time it takes to match a figure in FIG. 6(b). In this case, a method of measuring the time is as described for the item of MR_1.

For the measurement item of MR_2, as described above, it is performed by measuring an ability to quickly and accurately rotate a 3D forms, using an electronic display or a virtual reality (VR) display or an augmented reality (AR) display. A total of 14 questions (but not limited thereto) may be presented to measure the item of MR_2 for the user.

The spatial ability measurement system 10 in FIG. 3 stores the figures of the questions, the figures of the examples, and the correct answers for the questions corresponding to the measurement item of MR_2 in DB 150. When the measurement item of MR_2 is selected by the user, a corresponding question is extracted from the DB 150 and displayed to the user through an electronic display or VR or AR display. After an input of a rotation direction is received through the input device 142 and the figure of (a) that is rotated in a corresponding direction is displayed, when the displayed figure matches the figure of (b), a time during that process is measured.

Meanwhile, in the above, it has been described that the figures of the questions, the figures of the examples, and the correct answers are stored in the DB 150 with respect to the questions of the measurement item of MR_2, but the present invention is not limited thereto, and may be variously implemented. For example, only the figure corresponding to the question of the measurement item of MR_2 is stored in the DB 150, and when the question is displayed to the user, the corresponding figure may be presented only as a question, and the figure after the corresponding figure is vertically or horizontally rotated at least once based on a center of the corresponding figure may be provided as an example of the correct answer. As such, in a state in which only the figure of the question is stored in the DB 150, it is possible to generate and present a figure corresponding to an example in real time when the question is presented to the user.

Next, a measurement item of spatial visualization SV IA of the spatial visualization method will be described. As shown in [Table 1], the measurement item of spatial visualization SV IA is an item that measures an ability to read abstract 2D information and then convert it into a 3D figure, considering a viewing point. This measurement item is provided in an abstract form that allows a user to look at a 2D plan view and then imagine a 3D form of the 2D plan view provided as a question. The 2D and 3D information consists of elements of visualization that fit space, relationship, and eye level.

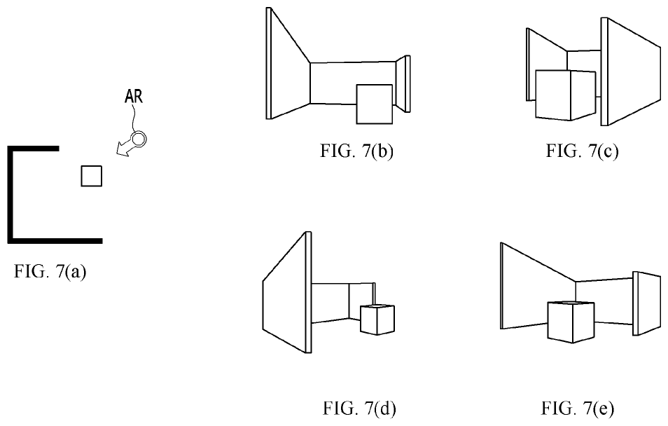

FIGS. 7(a)-7(e) illustrate a schematic view of a measurement item of spatial visualization SV IA of a spatial visualization method among spatial ability measurement methods according to an embodiment of the present invention.

Referring to FIG. 7(a) is a 2D plan view corresponding to a question for measuring spatial visualization SV IA, which is a view corresponding to a planar cross-sectional view of a 3D figure, and it is used to select a corresponding correct answer from figures in examples of FIG. 7(b), FIG. 7(c), FIG. 7(d), and FIG. 7(e) by imagining a 3D figure (which is a 3D figure for an interior space) when looking at the given 2D figure from a direction indicated by an arrow AR. Among the figures in the examples, there may be one or more correct answers, and in the examples of FIG. 7(e) is the correct answer, which corresponds to a 3D figure when the figure shown in FIG. 7(a) is viewed from the direction of the arrow AR.

User's answer input for the measurement item of the spatial visualization SV IA illustrated in FIGS. 7(a)-7(e) may be measured and used together with whether the answer is correct or incorrect and a time at which the answer is inputted. The time measurement may be performed in the same manner as described in FIGS. 5(a)-5(e).

For the measurement item of spatial visualization SV IA, as described above, it is performed by looking at a 2D plan view, imagining a space in a 3D form, and then submitting an answer, and in this case, for example, a total of 14 questions (but not limited thereto) may be presented to measure SV IA items of the spatial visualization for the user.

The spatial ability measurement system 10 in FIG. 3 stores the figures of the questions, the figures of the examples, and the correct answers for the questions corresponding to the measurement item of spatial visualization SV IA in DB 150, and when the measurement item SV IA of spatial visualization SV IA is selected by the user, a corresponding question may be extracted from the DB 150 and displayed to the user through the output device 141, and an answer may be inputted from the user through the input device 142. Alternatively, the questions corresponding to the measurement item of spatial visualization SV IA may be presented to the user in a form printed on paper, and an answer to each question may be received through the input device 142.

Meanwhile, in the above, it has been described that the figures of the questions, the figures of the examples, and the correct answers are stored in the DB 150 with respect to the questions of the measurement item of the spatial visualization SV IA, but the present invention is not limited thereto, and may be variously implemented. For example, only 3D figures corresponding to questions of the measurement item of spatial visualization SV IA are stored in the DB 150, and when displaying a question to the user, after extracting a part of the planar cross-sectional view of the stored 3D figure, an arrow AR is set in a direction in which an interior space thereof may be seen and then the part may be presented as a question (a), and a 3D perspective corresponding to the interior space when the stored 3D figure is viewed in the direction of the arrow AR may be provided as an example of a correct answer. In this case, other figures, for example, figures (which may have various other figures) in which some objects of 3D perspectives are viewed from a direction other than the direction of the arrow AR and a 3D perspectives viewed from the direction of the arrow AR in the saved 3D figure but part of the components are manipulated, distorted, enlarged or reduced, may be provided as figures of incorrect answers. As such, in a state in which only the target 3D figure is stored in the DB 150, when the question is presented to the user, it is possible to generate and present a 2D figure that is a planar sectional view corresponding to the question and 3D figures corresponding to examples, in real time.

Next, a measurement item of the spatial visualization 2, SV I of the spatial visualization method will be described. As shown in [Table 1], the measurement item of spatial visualization SV I measures an ability to expand 2D information to a 3D model or 3D interior space through 2D information. An ability of looking at a 2D plan view and then imagining a 3D figure is measured in the measurement item, and the measurement item consists of specific architecture/interior design drawing elements.

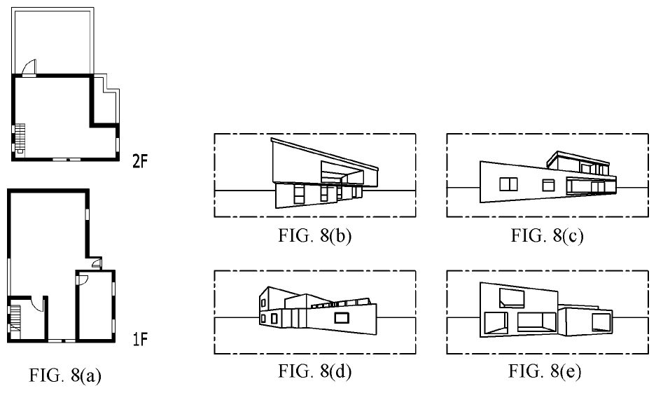

FIGS. 8(a)-8(e) illustrate a schematic view of a measurement item of spatial visualization SV I of a spatial visualization method among spatial ability measurement methods according to an embodiment of the present invention.

Referring to FIG. 8(a) is a 2D figure corresponding to a question for measuring spatial visualization SV I, and shows 2D plan view of first and second floors, that is, planar cross-sectional views of the first and second floors, and it is used to select a corresponding correct answer among 3D models (that is, external perspectives) in examples of FIG. 8(b), FIG. 8(c), FIG. 8(d), and FIG. 8(e) by looking at the given 2D plan view and then imagining a corresponding 3D model. Among the figures in the examples, there may be one or more correct answers, and in the examples of FIG. 8(d) is the correct answer, which corresponds to the 3D figure corresponding to the 2D plan view shown in FIG. 8(a).

User's answer input for the measurement item of the spatial visualization SV I illustrated in FIGS. 8(a)-8(e) may be measured and used together with whether the answer is correct or incorrect and a time at which the answer is inputted. The time measurement may be performed in the same manner as described in FIGS. 5(a)-5(e).

For the measurement item of spatial visualization SV I, as described above, it is performed by looking at a 2D plan view, imagining a 3D model, and then submitting an answer, and in this case, for example, a total of 20 questions (but not limited thereto) may be presented to measure an item of the spatial visualization for the user.

The spatial ability measurement system 10 in FIG. 3 stores the figures of the questions, the figures of the examples, and the correct answers for the questions corresponding to the measurement item of spatial visualization SV I in DB 150, and when the measurement item of spatial visualization SV I is selected by the user, a corresponding question may be extracted from the DB 150 and displayed to the user through the output device 141, and an answer may be inputted from the user through the input device 142. Alternatively, the questions corresponding to the measurement item of spatial visualization SV I may be presented to the user in a form printed on paper, and an answer to each question may be received through the input device 142.

Meanwhile, in the above, it has been described that the figures of the questions, the figures of the examples, and the correct answers are stored in the DB 150 with respect to the questions of the measurement item of the spatial visualization SV I, but the present invention is not limited thereto, and may be variously implemented. For example, only 3D figures corresponding to questions of the measurement item of spatial visualization SV I is stored in the DB 150, and when displaying a question to the user, a planar cross-sectional view (in case of multiple floors, a cross-sectional view is included for each floor) of the stored 3D figure may be extracted and presented as question (a), and a exterior or interior perspective view of the stored 3D figure may be provided as an example of a correct answer. In this case, another figure, for example, a figure in which the perspective view of the stored 3D figure is inverted, distorted, manipulated, or altered may be provided as a figure of a wrong answer. As such, in a state in which only the target 3D figure is stored in the DB 150, when the question is presented to the user, it is possible to generate and present a 2D figure corresponding to the question and 3D figures corresponding to examples, in real time.

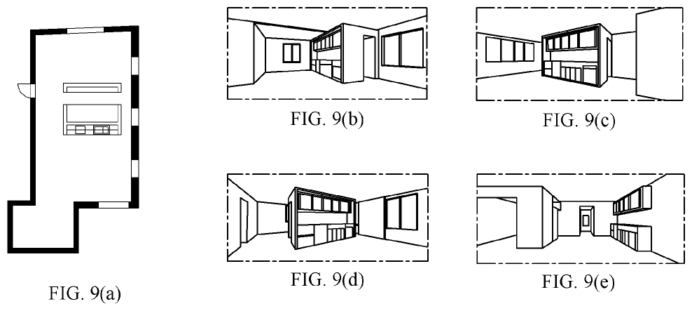

Meanwhile, the above-described measurement item of spatial visualization SV I may be presented as questions of other types as shown in FIGS. 9(a)-9(e).

FIGS. 9(a)-9(e) illustrate a schematic view of another example of a measurement item of spatial visualization SV I of a spatial visualization method among spatial ability measurement methods according to an embodiment of the present invention.

Referring to FIG. 9(a) is a 2D figure that corresponds to a question for measuring spatial visualization SV I, and is a plan view of a 3D figure. The user is asked to select a correct answer figure from examples of FIG. 9(b), FIG. 9(c), FIG. 9(d), and FIG. 9(e) corresponding to an interior perspective of the 2D plan view, by looking at the given 2D plan view and then imagining an interior space of a corresponding 3D figure. Among the figures in the examples, there may be one or more correct answers, and in the examples of FIG. 9(d) is the correct answer, which corresponds to the interior 3D figure of the 2D plan view shown in FIG. 9(a).

User's answer input for the measurement item of the spatial visualization SV I illustrated in FIGS. 9(a)-9(e) may be measured and used together with whether the answer is correct or incorrect and a time at which the answer is inputted. The time measurement may be performed in the same manner as described in FIGS. 5(a)-5(e).

For another example of the measurement item of spatial visualization SV I, as described above, it is performed by looking at a 2D plan view, imagining an interior space of a 3D figure, and then submitting an answer, and in this case, for example, a total of 20 questions (the questions in FIGS. 8(a)-8(e) and the questions in FIGS. 9(a)-9(e) may be added to set a total of 20, but is not limited thereto) may be presented to measure an item of the spatial visualization for the user.

For other contents, those of FIGS. 9(a)-9(e) may also be implemented as described in FIG. FIGS. 8(a)-8(e).

Next, a measurement item of the spatial visualization IISV II of the spatial visualization method will be described. As shown in [Table 1], the measurement item of spatial visualization SV II is an item for measuring an ability capable of converting 3D information to 2D configuration. An ability of looking at a 3D figure and then imagining a 2D figure is measured in the item, and the item consists of specific architecture/interior design drawing elements.

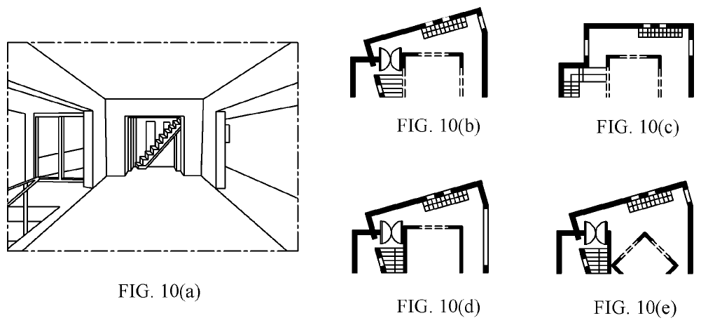

FIGS. 10(a)-10(e) illustrate a schematic view of a measurement item of spatial visualization SV II of a spatial visualization method among spatial ability measurement methods according to an embodiment of the present invention.

Referring to FIG. 10(a) is a 3D figure corresponding to a question for measuring spatial visualization SV II, and is a perspective view of a 3D interior space, and it is used to select a corresponding correct answer figure from examples of 2D planar cross-sectional views of FIG. 10(b), FIG. 10(c), FIG. 10(d), and FIG. 10(e) by looking at the given 3D figure and then imagining a corresponding 2D figure, that it, a planar cross-sectional view of the 3D figure shown in FIG. 10(a). Among the figures in the examples, there may be one or more correct answers, and in the examples of FIG. 10(b) is the correct answer, which corresponds to a 2D planar cross-sectional view corresponding to the 3D figure shown in FIG. 10(a).

User's answer input for the measurement item of the spatial visualization 3 illustrated in FIGS. 10(a)-10(e) may be measured and used together with whether the answer is correct or incorrect and a time at which the answer is inputted. The time measurement may be performed in the same manner as described in FIGS. 5(a)-5(e).

For the measurement item of spatial visualization 3, SV II, as described above, it is performed by looking at a 3D perspective, imagining a 2D planar cross-sectional view, and then submitting an answer, and in this case, for example, a total of 10 questions (but not limited thereto) may be presented to measure an item of the spatial visualization SV II for the user.

The spatial ability measurement system 10 in FIG. 3 stores the figures of the questions, the figures of the examples, and the correct answers for the questions corresponding to the measurement item of spatial visualization SV II in DB 150, and when the measurement item of spatial visualization SV II is selected by the user, a corresponding question may be extracted from the DB 150 and displayed to the user through the output device 141, and an answer may be inputted from the user through the input device 142. Alternatively, the questions corresponding to the measurement item of spatial visualization 3 may be presented to the user in a form printed on paper, and an answer to each question may be received through the input device 142.

Meanwhile, in the above, it has been described that the figures of the questions, the figures of the examples, and the correct answers are stored in the DB 150 with respect to the questions of the measurement item of the spatial visualization SV II, but the present invention is not limited thereto, and may be variously implemented. For example, only 3D figures corresponding to questions of the measurement item of spatial visualization 3 are stored in the DB 150, and when displaying a question to the user, a perspective view of the interior space of the stored 3D perspectives may be extracted and presented as question (a), and a planar cross-sectional view of the stored 3D figure may be provided as an example of a correct answer. In this case, another figure, for example, a figure in which the planar cross-sectional view of the space of the stored 3D figure is inverted, distorted, manipulated, or altered, may be provided as a figure of a wrong answer. As such, in a state in which only the target 3D figure is stored in the DB 150, when the question is presented to the user, it is possible to generate and present a 3D perspective corresponding to the question and 2D plan views corresponding to examples, in real time.

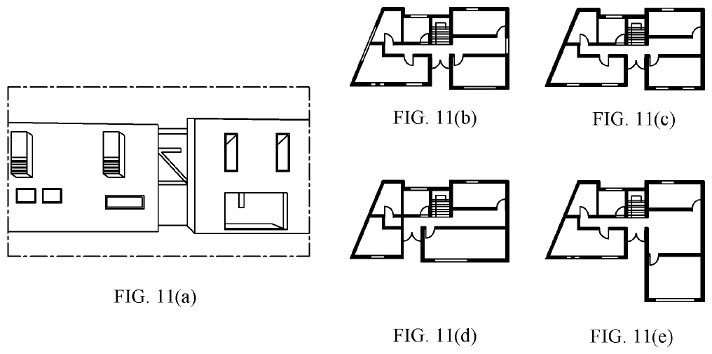

Meanwhile, the above-described measurement item of spatial visualization SV II may be presented as questions of other types as shown in FIGS. 11(a)-11(e).

FIGS. 11(a)-11(e) illustrate a schematic view of another example of a measurement item of spatial visualization SV II of a spatial visualization method among spatial ability measurement methods according to an embodiment of the present invention.

Referring to FIG. 11(a) is an exterior perspective view of a 3D model as the 3D figure that corresponds to a question for measuring spatial visualization SV II, and it is used to select a correct answer figure of a corresponding 2D planar cross-sectional view from examples of FIG. 11(b), FIG. 11(c), FIG. 11(d), and FIG. 11(e) by looking at the given 3D perspective and then imagining the corresponding 2D planar cross-sectional view. Among the figures in the examples, there may be one or more correct answers, and in the examples of FIG. 11(b) is the correct answer, which corresponds to a 2D planar cross-sectional view corresponding to the perspective view of the 3D model shown in FIG. 11(a).

User's answer input for the measurement item of the spatial visualization 3 illustrated in FIGS. 11(a)-11(e) may be measured and used together with whether the answer is correct or incorrect and a time at which the answer is inputted. The time measurement may be performed in the same manner as described in FIGS. 5(a)-5(e).

For another example of the measurement item of spatial visualization SV II, as described above, it is performed by looking at a 3D figure, a perspective view of the 3D model, imagining a planar cross-sectional view as 2D information, and then submitting an answer, and in this case, for example, a total of 10 questions (the questions in FIGS. 10(a)-10(e) and the questions in FIGS. 11(a)-11(e) may be added to set a total of 10, but is not limited thereto) may be presented to measure an item of the spatial visualization SV II for the user.

For other contents, those of FIGS. 10(a)-10(e) may also be implemented as described in FIGS. 11(a)-11(e).

Hereinafter, step S130 of performing the spatial ability measurement described in FIG. 4 will be described in detail with reference to FIGS. 5(a)-5(e) to FIGS. 11(a)-11(e) described above.

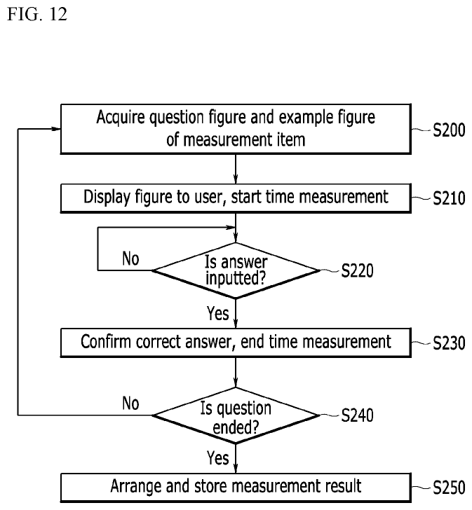

FIG. 12 illustrates a detailed flowchart of steps for performing spatial ability measurement illustrated in FIG. 4.

Referring to FIG. 12, first, a question figure, an example figure, and a correct answer corresponding to a question of each method for performing spatial ability measurement are extracted from, for example, the DB 150 (S200). Referring to FIGS. 5(a)-5(e) and FIGS. 7(a)-7(e) to FIGS. 11(a)-11(e) described above, the correct answer is extracted together with the figures for each question.

Next, by displaying a question consisting of the extracted figure to the user, the spatial ability measurement according to the embodiment of the present invention starts (S210). At this time, time measurement through a timer (not shown) may be started.

Thereafter, it is determined whether an answer to the question is inputted from the user (S220), and if an answer is inputted, the inputted answer is compared with the correct answer extracted in step S200 to determine whether the inputted answer is correct (S230). At this time, when the time measurement through the timer (not shown) is in progress, the time measurement ends.

Then, after confirming whether the question has ended because no other questions remain (S240), if other questions remain, the above steps S200, S210, S220, and S230 for a next question are repeated.

If it is determined that in step S240, the question has ended because there is no other question, whether the correct answer is determined for each question is arranged as a measurement result and stored corresponding to the user (S250).

Step S140 of performing the spatial ability evaluation in FIG. 4 on the stored measurement result will be continuously performed.

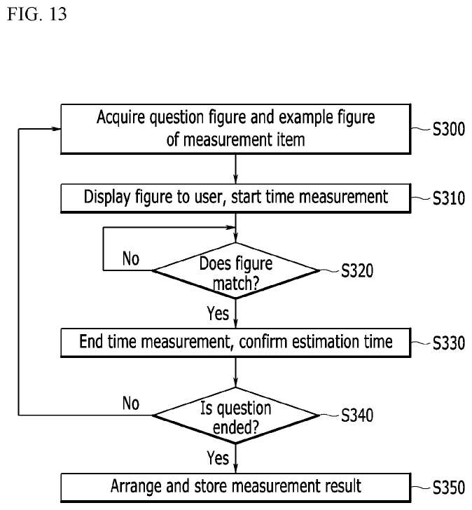

Meanwhile, the measurement item of MR_2 illustrated in FIGS. 6(a)-6(b) may be performed in a slightly different method from the method illustrated in FIG. 12, which will be described with reference to FIG. 13.

FIG. 13 illustrates another flowchart of steps for performing spatial ability measurement illustrated in FIG. 4.

Referring to FIG. 13, first, a question figure, an example figure, and a correct answer corresponding to a question of each method for performing spatial ability measurement are extracted from, for example, the DB 150 (S300). Referring to FIGS. 6(a)-6(b) described above, the correct answer is extracted together with the figures for each question.

Next, by displaying a question consisting of the extracted figure through a VR display (not shown) to the user, the spatial ability measurement according to the embodiment of the present invention starts (S310). At this time, time measurement through a timer (not shown) may be started.

Thereafter, the question figure displayed on the VR display is rotated by the user, and it is determined whether the rotated figure and the figure displayed in FIG. 6(b) match (S320), then when the figures match, the time measurement of the question is ended, and the measured time of the question is checked (S330).

Then, after confirming whether the question has ended because no other questions remain (S340), if other questions remain, the above steps S300, S310, S320, and S330 for a next question are repeated.

If it is determined that, in step S340, the question has ended because there is no other question, the time determined and measured for each question is arranged as a measurement result and stored corresponding to the user (S350).

Step S140 of performing the spatial ability evaluation in FIG. 4 on the stored measurement result will be continuously performed.

Meanwhile, for each measurement item of FIGS. 5(a)-5(e) to FIGS. 11(a)-11(e) described above, only basic 3D figures are stored in advance for each question, and the method of extracting and providing the question figure and the example figure from the stored basic 3D figures has been described.

Therefore, step S130 of performing the spatial ability measurement described in FIG. 4 corresponding to this method will be described.

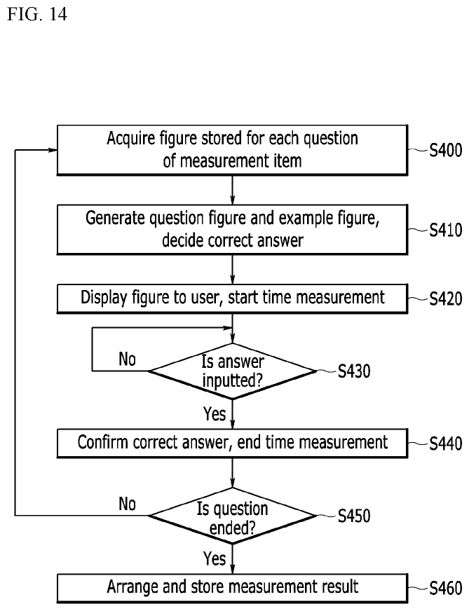

FIG. 14 illustrates another flowchart of steps for performing spatial ability measurement illustrated in FIG. 4.

Referring to FIG. 14, first, a basic 3D figure stored corresponding to a question of each method for performing spatial ability measurement is extracted from, for example, the DB 150 (S400).

Next, the extracted basic 3D figure is generated to be used as a figure of the question and the example figures are generated and displayed and then the user decides the correct answer (S410).

Thereafter, the figure of the generated question and the example figures are displayed to the user, so that the spatial ability measurement according to the embodiment of the present invention is started (S420). At this time, time measurement through a timer (not shown) may be started.

Thereafter, it is determined whether an answer to the question is inputted from the user (S430), and if an answer is inputted, the inputted answer is compared with the correct answer decided in step S410 to determine whether the inputted answer is correct (S440). At this time, when the time measurement through the timer (not shown) is in progress, the time measurement ends.

Then, after confirming whether the question has ended because no other questions remain (S450), if other questions remain, the above steps S400, S410, S420, S430, and S440 for a next question are repeated.

If it is determined that in step S450, the question has ended because there is no other question, whether the correct answer is determined for each question is arranged as a measurement result and stored corresponding to the user (S460).

Step S140 of performing the spatial ability evaluation in FIG. 4 on the stored measurement result will be continuously performed.

Meanwhile, in the case in which the flow of the method according to FIG. 14 described above is applied to FIGS. 6(a)-6(b) described above, when the implementation corresponding to the difference between the flow in FIG. 12 and the flow in FIG. 13 is applied to FIG. 14, it will be readily understood by those skilled in the art that they may be applied to the measurement items of FIGS. 6(a)-6(b) as in those of FIG. 14.

All spatial ability measurement in the present invention can be implemented in various methods of display and interaction with the user. For example, when using virtual reality display for the second mental rotation measurement (MR_2) or other displays, including, but not limited to computer screens, head mounted displays, and Augmented reality displays.

The above-described embodiments can be realized through a program for realizing functions corresponding to the configuration of the embodiments or a recording medium for recording the program in addition to through the above-described device and/or method, which is easily realized by a person skilled in the art.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of measuring a spatial ability required in the field of architecture or interior design, comprising:
performing one or more of a mental rotation measurement and a spatial visualization measurement for a user in order to measure a spatial ability for the user;
evaluating spatial ability for the user according to a result of performing the one or more measurements; and
providing the evaluated result to the user as a spatial ability required for architecture or interior design,
wherein the mental rotation measurement is performed by measuring the accuracy and speed of a rotation state estimation ability for a 3D (three-Dimension) figure, and
the spatial visualization measurement is performed by measuring an ability of translating a 3D spatial information into 2D (two-Dimension) spatial information and an ability of translating a 2D spatial information into a 3D spatial information.

2. The method of measuring the spatial ability of claim 1, wherein
the mental rotation measurement includes
a first mental rotation measurement of measuring a state estimation ability after rotating a 3D figure at a predetermined angle based on a vertical axis, and
a second mental rotation measurement of measuring rapidity of rotation of a 3D figure at least one or more in up, down, left, and right directions.

3. The method of measuring the spatial ability of claim 2, wherein
the first mental rotation measurement is performed by a method in which, after providing a 3D figure as a question to the user and providing a plurality of 3D figures of different forms as examples, the user estimates a state after rotating the 3D figure of the question based on the vertical axis and then selects two matching 3D figures as an answer from the example figures.

4. The method of measuring the spatial ability of claim 3, wherein
the second mental rotation measurement is performed by a method in which, after providing a 3D figure as a question to the user and providing a 3D figure as an example formed by the 3D figure of the question being rotated at least one or more times in up, down, left, and right directions, a time until the user rotates the 3D figure of the question at least one or more times in up, down, left, and right directions to match the 3D figure of the example is measured.

5. The method of measuring the spatial ability of claim 4, wherein after the 3D figure of the question and the 3D figure of the example are displayed to the user through a virtual reality display or an augmented display, the second mental rotation measurement is performed by rotating the 3D figure of the question using the virtual reality display or the augmented display.

6. The method of measuring the spatial ability of claim 1, wherein
the spatial visualization measurement includes
a first spatial visualization measurement that measures an ability of translating 2D planar cross-sectional view of an abstract 3D spatial figure into a corresponding 3D abstract spatial form, when a partial 2D planar cross-sectional view of a 3D figure is viewed,
a second spatial visualization measurement that measures an ability of translating a 2D planar cross-sectional view of a 3D spatial figure having at least one or more floors into a corresponding 3D exterior perspective or a 3D internal perspective, and
a third spatial visualization measurement that measures an ability of translating a 3D spatial figure of both exterior and interior spaces into corresponding 2D planar cross-sectional view.

7. The method of measuring the spatial ability of claim 6, wherein
the first spatial visualization measurement is performed by a method in which, after providing a 2D planar cross-sectional view—in the 2D cross-sectional view, one side thereof is open, and an arrow of a type viewed from the opened side is indicated—of an abstract 3D figure to the user as a question and providing a plurality of 3D figures having different shapes as an example, the user estimates a 3D space when looking at the 2D planar cross-sectional view from the direction of the arrow and then selects a matching 3D figure with the estimated volumetric forms of the figures in the example as an answer.

8. The method of measuring the spatial ability of claim 6, wherein
the second spatial visualization measurement is performed by a method in which, after providing at least one 2D planar cross-sectional view of a 3D spatial figure having at least one or more floors to the user as a question and providing a plurality of 3D spatial figures having different forms as an example, the user estimates the 3D exterior spatial forms and volumes or a 3D interior spatial forms and volumes of a space represented by the 2D planar cross-sectional view and then selects a matching 3D exterior or interior perspective view of the space as an answer.

9. The method of measuring the spatial ability of claim 6, wherein
the third spatial visualization measurement is performed by a method in which, after providing a 3D exterior perspective or a 3D interior perspective as a question and providing a plurality of 2D planar cross-sectional views having different shapes as an example, the user estimates a 2D planar cross-sectional view of the space represented by a 3D exterior perspective or a 3D interior perspective in the question and then selects a matching 2D planar cross-sectional view of the space as an answer.

10. The method of measuring the spatial ability of claim 1, wherein
the performing of one or more of the mental rotation measurement and the spatial visualization measurement for the user includes:
acquiring a 2D or 3D figure corresponding to a pre-stored question and a 2D or 3D figure corresponding to the example for the pre-stored question to perform the mental rotation measurement or the spatial visualization measurement;
presenting a question including the 2D or 3D figure corresponding to the question and the 2D or 3D figure corresponding to the example to the user;
receiving an answer to the question from the user to determine whether the received answer is correct or incorrect; and
reporting the result of determining whether the received answer is correct or incorrect as a result of performing the measurement.

11. The method of measuring the spatial ability of claim 10, wherein
the presenting of the question to the user includes
displaying the question to the user through the virtual reality display or the augmented display;
the receiving of the answer to the question from the user to determine whether the received answer is correct or incorrect includes
measuring a time until the user rotates a 3D figure corresponding to the question displayed on the virtual reality display in at least one of up, down, left, and right directions to match the 3D figure corresponding to the example; and
reporting as the results of performing the measurement includes reporting the time measured for each question as the result of performing the measurement.

12. The method of measuring the spatial ability of claim 1, wherein
the performing of one or more of the mental rotation measurement and the spatial visualization measurement for the user includes:
acquiring a basic 3D figure corresponding to a pre-stored question for the mental rotation measurement or the spatial visualization measurement;
generating a 2D or 3D figure corresponding to a question and a 2D or 3D figure corresponding to an example in real time by using the basic 3D figure;
presenting a question including the 2D or 3D figure corresponding to the question generated in real time and the 2D or 3D figure corresponding to the example to the user;
receiving an answer to the question from the user and determining whether the received answer is correct; and
setting the result of determining whether the received answer is correct as a result of performing the measurement.

13. A system of measuring a spatial ability required in a field of architecture of interior design, comprising
an input/output part, a memory, and a processor,
wherein the input/output part displays information or outputs voice to the outside and receives information or instructions inputted from the outside;
the memory is configured to store a set of codes;
the codes control the processor to execute
a process of performing one or more of mental rotation measurement and spatial visualization measurement for the user based on display of information through the input/output part and input from a user,
a process of evaluating a spatial ability required in the field of architecture or interior design for the user according to a result of performing the one or more measurements, and
a process of providing the evaluated result to the user as process measurement of spatial ability through the input/output part; and
the mental rotation measurement is performed by measuring a rotation state estimation ability for a 3D figure, and
the spatial visualization measurement is performed by measuring an ability of translating 3D spatial information into 2D spatial information and an ability of translating a 2D spatial information into a 3D spatial information.

14. The system of measuring the spatial ability of claim 13, wherein
the processor, for the mental rotation measurement,
measures an ability of estimating a state after rotation at a predetermined angle based on a vertical axis of a 3D figure, and
further executes a process of measuring rapidity of rotation of at least one or more times in up, down, left, and right directions of a 3D figure.

15. The system of measuring the spatial ability of claim 14, wherein
the spatial ability measurement system further includes a virtual reality display or an augment display, and
the processor uses the virtual reality display to execute the process of displaying the questions and measuring the spatial ability required in the field of architecture or interior design.

16. The system of measuring the spatial ability of claim 13, wherein
the processor, for the spatial visualization measurement, further executes
a process of measuring an estimation ability of a 3D interior space when a partial 2D planar cross-sectional view view of a 3D figure is viewed from a predetermined direction,
a process of measuring an estimation ability of a 3D external elevation figure or a 3D internal space through at least one 2D planar cross-sectional view of a 3D figure having at least one or more floors, and
a process of measuring an estimation ability of a corresponding 2D planar cross-sectional view through a 3D exterior elevation figure or a 3D interior space figure.

17. The system of measuring the spatial ability of claim 13, wherein
the processor, when executing the process of performing the one or more of the mental rotation measurement and the spatial visualization measurement for the user, further executes
a process of acquiring a 2D or 3D figure corresponding to a pre-stored question and a 2D or 3D figure corresponding to a pre-stored example and providing them to the user through the input/output part, and
a process of receiving an answer inputted from the user through the input/output part and setting it as the result of performing the measurement.

18. The system of measuring the spatial ability of claim 13, wherein
the processor, when executing the process of performing the one or more of the mental rotation measurement and the spatial visualization measurement for the user, further executes
a process of acquiring a basic 3D figure corresponding to a pre-stored question,
a process of generating a 2D or 3D figure corresponding to the question and a 2D or 3D figure corresponding to the example in real time by using the acquired basic 3D figure and then providing them to the user through the input/output part, and
a process of receiving an answer inputted from the user through the input/output part and setting it as the result of performing the measurement.
